(19) United States
(12) Patent Application Publication
(10) Pub. No.: US 2009/0115021 A1
(43) Pub. Date: May 7, 2009

(54) ANTIFUSE ELEMENT IN WHICH MORE THAN TWO VALUES OF INFORMATION CAN BE WRITTEN

(75) Inventor: YOSHIKAZU MORIWAKI, Tokyo (JP)

Correspondence Address: YOUNG & THOMPSON, 209 Madison Street, Suite 500, ALEXANDRIA, VA, 22314, US

(73) Assignee: ELPIDA MEMORY, INC., TOKYO (JP)

(21) Appl. No.: 12/262,768

(22) Filed: Oct. 31, 2008

(30) Foreign Application Priority Data
Nov. 2, 2007 (JP) 2007-286131

(51) Int. Cl. H01L 29/00; H01H 85/00

(52) U.S. Cl. 257/530; 327/525; 257/E29.001

(57) ABSTRACT

An antifuse element includes a plurality of MOS transistors; a first electrode to which source electrodes of the plurality of MOS transistors are commonly connected; a second electrode to which gate electrodes of the plurality of MOS transistors are commonly connected; a third electrode to which at least one of drain electrodes of the plurality of MOS transistors is capable of being connected; and an insulation film provided between the drain electrodes of the plurality of MOS transistors and the third electrode, wherein the insulation on at least one position in said insulation film and that corresponds to one of the drain electrodes is broken down.

This application is based upon and claims the benefit of priority from Japanese Patent Application No. 2007-286131 filed on Nov. 2, 2007, the content of which is incorporated by reference.

### BACKGROUND OF THE INVENTION

1. Field of the Invention

The present invention relates to an antifuse element for changing a circuit connection in a semiconductor device, and a method for setting the antifuse element.

2. Description of Related Art

In a semiconductor memory, a fuse is used to improve the production yield by substituting, with a spare substitution cell (redundant cell), a defective memory cell induced because of a foreign particle during manufacturing or because of an irregular memory cell whose refresh characteristic is irregular because of production fluctuation of a DRAM (Dynamic Random Access Memory). The fuse is also used in a circuit for adjusting the reference voltage in a reference voltage generating circuit in a semiconductor memory chip. Such a fuse is roughly classified as a laser trimmer fuse and an antifuse. Meanwhile, hereinafter, the defective memory cell and also the irregular memory cell are referred to as a defective memory cell.

In the case of DRAM, the laser trimmer fuse is used to save a circuit by substituting the defective memory cell with the redundant cell. By cutting the fuse with a laser trimmer apparatus, a circuit is caused to change from conductive to non-conductive, thereby, the redundant cell is substituted for the defective memory cell. However, such a circuit saving by the fuse includes such a fault that the throughput is low, and the laser trimmer apparatus can not be used after packaging. On the other hand, U.S. Pat. No. 4,899,205 (hereinafter, referred to as Patent Document 1) discloses a semiconductor device in which the antifuse is mounted in a chip, which can save a circuit having a fault even after packaging.

In the antifuse, a wiring for switching the defective memory cell to the redundant cell is initially non-conductive, and is changed to a conductive state by an operation such as voltage being applied from outside.

A configuration of the antifuse will be described. FIG. 1A and FIG. 1B are pattern views illustrating an exemplary configuration of the related antifuse. FIG. 1A is a plain view of the antifuse, and FIG. 1B is a cross-section view at line X-X′ of FIG. 1A.

As illustrated in FIG. 1A and FIG. 1B, like a MOS (Metal Oxide Semiconductor) transistor, the antifuse is configured with gate electrode 101, and active area 105 including diffusion layer 109a and diffusion layer 109c. Diffusion layer 109a corresponds to a source electrode, and diffusion layer 109c corresponds to a drain electrode. However, diffusion layers 109a and 109c, and semiconductor substrate 8 are connected by one electrode and in this point are different from the MOS transistor. This electrode denotes drain electrode 102.

Gate electrode 101 is formed on semiconductor substrate 8 through gate insulation film 106. A MOS structure is configured with gate electrode 101, gate insulation film 106, and semiconductor substrate 8. The antifuse is insulated by isolation portion 7 from an adjacent element.

Two kinds of information can be recorded by conditions of the antifuse, whether or not the antifuse is conductive. It is assumed that the recorded information is “1” when the antifuse is conductive, and the recorded information is “0” when the antifuse is not conductive.

A writing method for writing information will be described, and the method is implemented by setting the antifuse illustrated in FIG. 1A and FIG. 1B to be conductive, or to be non-conductive.

When the information “1” is written in the antifuse, the antifuse is caused to be conductive as follows. A voltage of around 4.0 V is applied to gate electrode 101, a pulse voltage of around −2.0 V is applied to diffusion layer 109c through drain electrode 102, thereby, gate insulation film 106 is broken down, and the fuse is caused to be conductive. An arrow illustrated as the reference number 110 in FIG. 1A and FIG. 1B indicates the path of current that flows when the information is written.

Next, a reading method for reading the information of the antifuse will be described.

FIG. 2A and FIG. 2B are views describing the reading method for reading the information of the antifuse illustrated in FIG. 1A and FIG. 1B. FIG. 2A is a plain view of the antifuse, and FIG. 2B is a cross-section view at line X-X′ of FIG. 2A.

When the information that has been written into the antifuse is read, as illustrated in FIG. 2A and FIG. 2B, a voltage of around 1.5 V is applied to gate electrode 101, and a voltage of 0 V is applied to diffusion layer 109c through drain electrode 102. It becomes possible to determine from a value of current 111 that flows in the antifuse whether the information written into the antifuse is the information “0” (non-conductive) or the information “1” (conductive).

In the above antifuse, only two values, information “0” or information “1”, can be recorded. When many defective memory cells are included in the semiconductor memory, or the like, and when such many defective memory cells are replaced with normal cells respectively by using the above antifuse, fuses for switching a circuit connection become necessary, whose number is the same as that of the defective memory cells. Thus, to save the many defective memory cells, the fuses, whose number corresponds to the number of the defective memory cells, are needed, and it becomes necessary to secure a wide area for allocating such fuses in a redundant circuit. As a result, a chip size becomes larger.

### SUMMARY

In one embodiment, there is provided an antifuse element that includes a plurality of MOS transistors; a first electrode to which source electrodes of the plurality of MOS transistors are commonly connected; a second electrode to which gate electrodes of the plurality of MOS transistors are commonly connected; a third electrode to which at least one of the drain electrodes of the plurality of MOS transistors is capable of being connected; and an insulation film provided between the drain electrodes of the plurality of MOS transistors and the third electrode, wherein the insulation on at least one position in the insulation film and that corresponds to one of the drain electrodes is broken down.

### BRIEF DESCRIPTION OF THE DRAWINGS

The above features and advantages of the present invention will be more apparent from the following description of certain preferred embodiments taken in conjunction with the accompanying drawings, in which:

FIG. 1A and FIG. 1B are pattern views illustrating an exemplary configuration of a related antifuse;

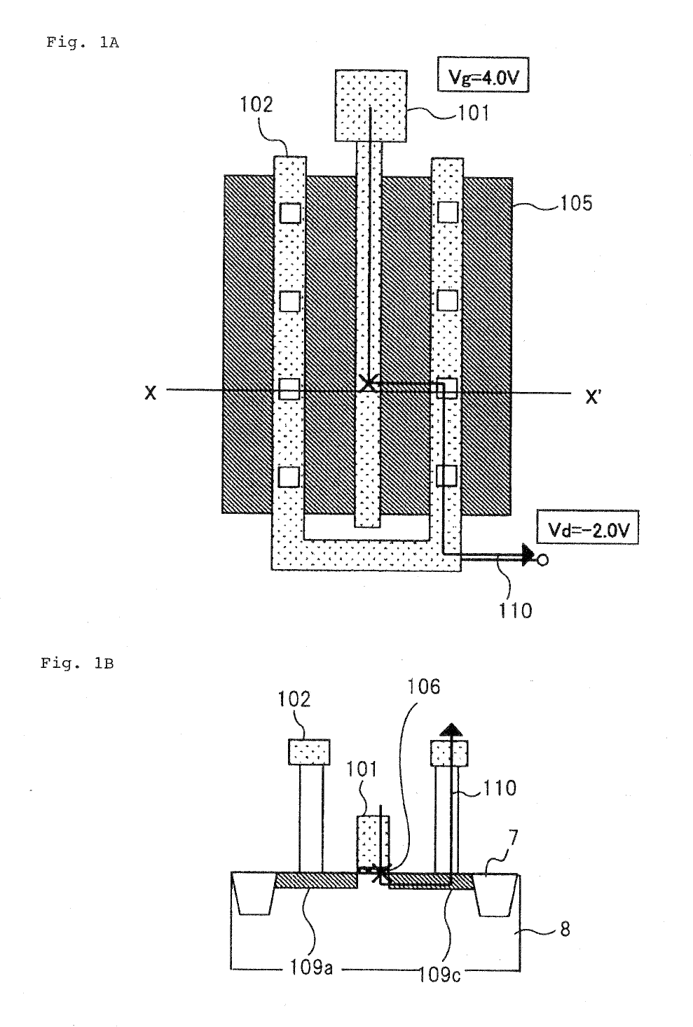

FIG. 2A and FIG. 2B are views describing a reading method for reading information that has been written into the antifuse illustrated in FIG. 1A and FIG. 1B;

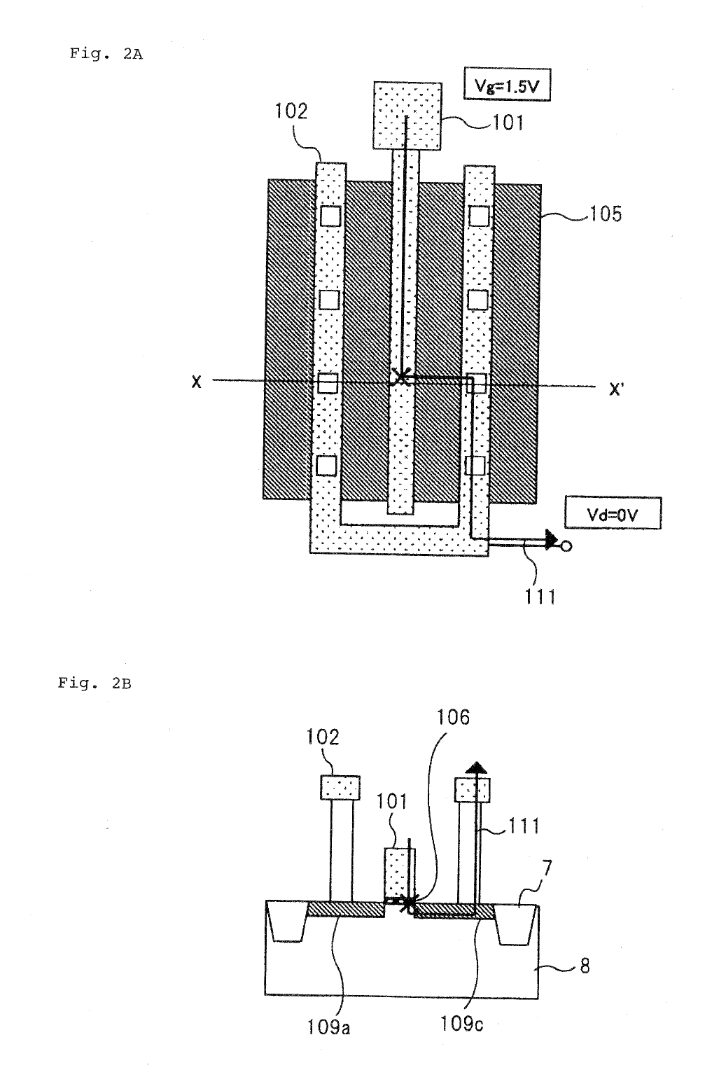

FIG. 3A and FIG. 3B are views illustrating an exemplary configuration of the antifuse of a first exemplary embodiment;

FIG. 4A and FIG. 4B are views describing a writing method for writing information into the antifuse of the first exemplary embodiment;

FIG. 5A and FIG. 5B are views describing a reading method for reading information in the antifuse of the first exemplary embodiment;

FIG. 6A and FIG. 6B are views describing a writing method for writing information into the antifuse of a second exemplary embodiment; and

FIG. 7A and FIG. 7B are views describing a reading method for reading information in the antifuse of the second exemplary embodiment.

### DETAILED DESCRIPTION OF THE PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposes.

### First Exemplary Embodiment

A configuration of an antifuse of the present exemplary embodiment will be described. The present exemplary embodiment will be described in such a case in which a maximum of five values of information can be recorded in a fuse.

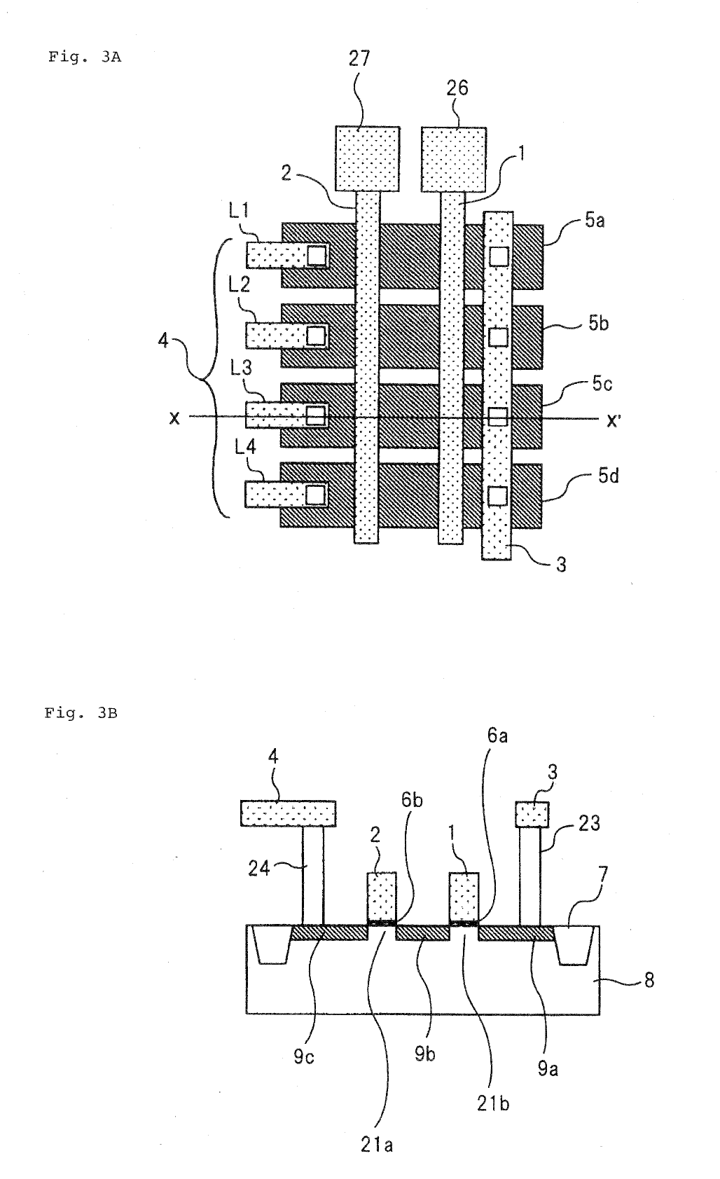

FIG. 3A and FIG. 3B are views illustrating an exemplary configuration of the antifuse of the present exemplary embodiment. FIG. 3A is a plain view of the antifuse, and FIG. 3B is a cross-section view at line X-X′ of FIG. 3A.

In the antifuse of the present exemplary embodiment, an active area is provided on a surface of P-type semiconductor substrate 8, which includes diffusion layers 9a to 9c in which a N-type impurity is introduced, and channel areas 21a and 21b, and the active area is divided to four areas. The divided areas are referred to as divided areas 5a to 5d respectively. Isolation portion 7 such as the STI (Shallow Trench Isolation) is provided between the divided areas.

As illustrated in FIG. 3A, two wirings among four divided areas 5a to 5d are provided in parallel as separated from each other by a predetermined distance. One of the two wirings covers channel area 21b of each divided area through gate insulation film 6a. This wiring connects gate electrodes of MOS transistors corresponding to the divided areas, and plays the role of common gate electrode 1 as a whole. While the other of the above two wirings covers, like gate electrode 1, channel area 21a of each divided area through gate insulation film 6b, the other wiring is, by an after-mentioned method, connected to a drain electrode which is any one of a plurality of diffusion layers 9b. Thus, hereinafter, this wiring is referred to as drain electrode 2.

Gate electrode 1 is provided with electrode pad 26 for connecting gate electrode 1 to wiring that is not illustrated. Drain electrode 2 is provided with electrode pad 27 for connecting drain electrode 2 to wiring that is not illustrated.

Diffusion layer 9c of each divided area is connected to the corresponding wiring of wirings L1 to L4 through plug 24. Wirings L1 to L4 function as the wiring for selecting diffusion layer 9b of the divided area, to which drain electrode 2 is to be connected. Hereinafter, such a wiring is referred to as break selection wiring 4. Diffusion layers 9a of four divided areas 5a to 5d are connected to one wiring through plugs 23. This wiring is referred to as source electrode 3.

In the above configuration, the antifuse of the present exemplary embodiment includes the four MOS transistors including common gate electrode 1, source electrode 3 which connects diffusion layers 9a of the four MOS transistors, drain electrode 2 connected to at least any one of diffusion layers 9b of the four MOS transistors, and gate insulation film 6b, which corresponds to diffusion layers 9b, provided between diffusion layers 9b and drain electrode 2. Meanwhile, source electrode 3 corresponds to a first electrode of the present invention, gate electrode 1 corresponds to a second electrode of the present invention, and drain electrode 2 corresponds to a third electrode of the present invention.

The Poly-Si (polysilicon), in which the impurity is introduced, can be used as gate electrode 1, drain electrode 2, and source electrode 3. Not only a single layer of the Poly-Si, in which the impurity is introduced, but also a multiple layer may be used which is obtained by stacking the Poly-Si film, in which the impurity is introduced, and by stacking a high melting point metal film or a high melting point metal silicide film.

Since it is desirable that a resistance value of the gate electrode of the MOS transistor is normally low, when Poly-Si is used for material of the electrode as described above, a conductive impurity is uniformly diffused by the high density of 1E 20/cm³ in the Poly-Si. Thus, the resistance value of the gate electrode of the MOS transistor is low, and the gate insulation film is not broken down by the voltage applied to the gate electrode, so that the voltage drop is extremely small, which is induced because of current that flows in the gate electrode. The resistance value of source electrode 3 is also low as in the gate electrode.

On the other hand, the resistance value of drain electrode 2 of the present exemplary embodiment is caused to be higher as compared with the normal gate electrode Because of the characteristics of a resistor, the greater the distance in drain electrode 2, the higher is the resistance value. As illustrated in FIG. 3A, the distances in drain electrode 2 are different from the distances in electrode pad 27 to each divided area. In comparing such distances, the distance from electrode pad 27 to divided area 5a is the shortest, and the distance from electrode pad 27 to divided area 5d is the longest. Thus, when the voltage is applied to electrode pad 27, and when the current flows in drain electrode 2, the longer the distance from electrode pad 27, the larger is the voltage drop.

A method for using a pattern and a method for using impurity density are included in a method for enlarging the resistance value and the voltage drop according to the distance from electrode pad 27. In the method for using a pattern, a pattern of drain electrode 2 is caused to be a zigzag-type instead of a linear type as illustrated in FIG. 3A, thereby, the wiring length of drain electrode 2 is caused to be longer. In the method for using the impurity density, the density of the impurity which is introduced in the Poly-Si of drain electrode 2 is adjusted, thereby, the electric resistivity of the electrode is caused to be higher than that of gate electrode 1. Not only one, but also both of such two methods may be used.

In the method for increasing a resistance value by adjusting the density of the impurity which is introduced in the Poly-Si, not only the density of the N-type impurity is decreased, but also the resistance value of the electrode may be increased by doping the contrarily conductive P-type impurity into the Poly-Si in which the N-type impurity has been introduced. In such a case, while phosphorus is introduced as the N-type impurity in the Poly-Si, a mask for a photoresist is formed, in which an aperture is formed in a part corresponding to the drain electrode, and boron, which is the P-type impurity, may be ion-implanted through the aperture.

As described above, in drain electrode 2 of the present exemplary embodiment, the resistance value and the voltage drop from electrode pad 27 to the divided area are more largely changed in proportion to the distance from electrode pad 27 as compared with the normal electrode. The method for adjusting the impurity density is used for drain electrode 2 as illustrated in FIG. 3A.

Meanwhile, a method for manufacturing the antifuse in the present exemplary embodiment is the same as a normal manufacturing method for manufacturing the antifuse, except that, when gate electrode 1 and drain electrode 2 are formed, the mask pattern in the lithography process is different, the impurity doping density for drain electrode 2 is different, and the forming process for forming break selection wiring 4 is added, so that a detailed description will be omitted.

Next, a writing method for writing information into the antifuse in the present exemplary embodiment will be described. It is assumed that the voltage applied to source electrode 3 is Vs, the voltage applied to drain electrode 2 is Vd, and the voltage applied to semiconductor substrate 8 is Vsub.

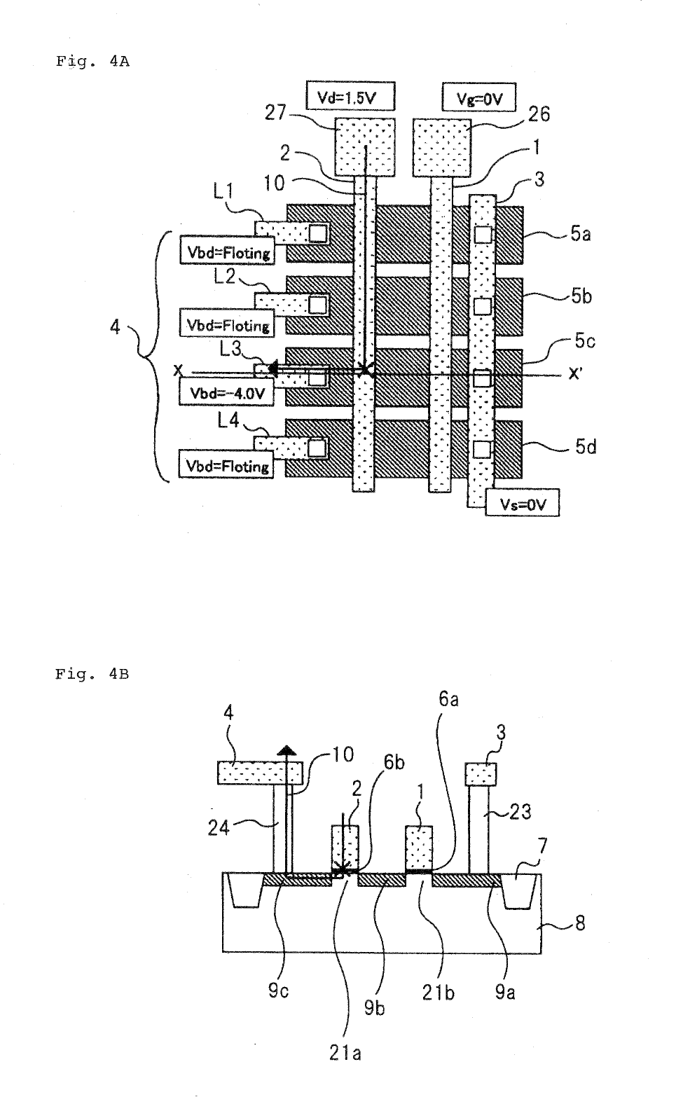

FIG. 4A and FIG. 4B are views describing the method for writing information into the antifuse of the present exemplary embodiment.

An applied voltage (vg) to gate electrode 1 is defined as threshold voltage Vt, which is necessary for the drain current of the MOS transistor to reach a predetermined value. As an example, in the definition of I=1μ A/gate width 10 μm, Vt=0.5 V. The gate width is a length of gate electrode 1 in a direction that crosses the current direction in channel area 21b between diffusion layer 9a of source electrode 3 and diffusion layer 9b of drain electrode 2.

One of wrings L1 to L4 of break selection wiring 4 is selected. Here, wring L3 is selected. The voltage of gate electrode 1, source electrode 3, and semiconductor substrate 8 is caused to be 0 V (earth condition) (Vg=Vs=Vsub=0 V). As breakdown voltage (hereinafter, expressed as Vbd) of gate insulation film 6b, Vbd=around −4.0 V is applied to wring L3. A voltage pulse of Vd=around 1.5 V is applied to drain electrode 2. Thereby, in divided area 5c, gate insulation film 6b of a lower part of drain electrode 2 is broken down, and as illustrated in the current path of arrow 10 in FIG. 4A and FIG. 4B, drain electrode 2 becomes conductive with diffusion layers 9b and 9c. The Vt of the MOS transistor is set according to the wiring resistance of drain electrode 2, whose length is a length from electrode pad 27 to divided area 5c.

Since one wiring is selected from wirings L1 to L4, a divided area is established, which includes diffusion layer 9b to be caused to be conductive with drain electrode 2. Since the divided area is established, an effective length from electrode pad 27 of drain electrode 2 is established, and the resistance of drain electrode 2 is established according to such a length. That is, according to the selected wiring of wirings L1 to L4, one resistance value of drain electrode 2 is selected from four kinds of resistance values.

The relationship between the resistance values in drain electrode 2 is as follows, as indicated by the wirings; L1<L2<L3<L4. Even when any wiring is selected to turn on the MOS transistor, it is necessary to increase the voltage to be applied by the voltage drop because of the resistance of drain electrode 2. Thus, like the above the relationship of the resistance, the value of the Vt is the smallest when wiring L1 is selected, and is the largest when wiring L4 is selected.

Next, a method for reading information written into the antifuse of the present exemplary embodiment will be described. Here, as illustrated in FIG. 4A, it is assumed that wiring L3 has been selected.

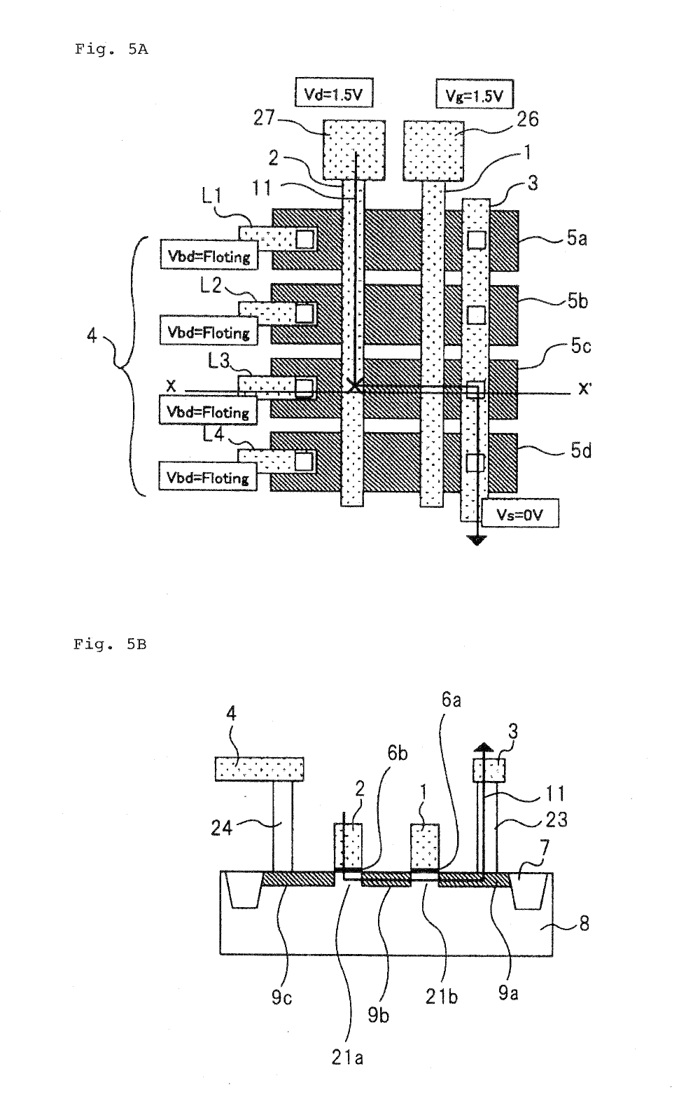

FIG. 5A and FIG. 5B are views describing the method for reading information that has been written into the antifuse of the present exemplary embodiment.

All wirings L1 to L4 of break selection wiring 4 are floating states. The voltage for turning on the normal MOS transistor is applied to each of drain electrode 2, gate electrode 1 source electrode 3, and semiconductor substrate 8.

Since gate insulation film 6b of a lower part of drain electrode 2 in divided area 5c is broken down, diffusion layer 9b is conductive with drain electrode 2 in the MOS transistor. Thus, when the voltage applied to source electrode 3 and semiconductor substrate 8 is Vs=Vsub=0 V, and when the voltage of Vg=Vd=1.5 V is applied to drain electrode 2 and gate electrode 1, the drain current flows in the current path of arrow 11 as illustrated in FIG. 5A and FIG. 5B. The transistor is thereby turned on by the threshold voltage set by selecting wiring L3.

In the antifuse of the present exemplary embodiment, since one wiring is selected from wirings L1 to L4 in break selection wiring 4, and since the voltage for breaking the insulation film of the lower part of drain electrode 2 is applied to the selected wiring, a length of drain electrode 2 is established. Next, the threshold voltage is set to the transistor, which corresponds to the voltage drop in drain electrode 2. Since one value can be selected from a plurality of the threshold voltages whose values are different from each other, multiple values can be outputted. Even when the transistor is turned off, the threshold voltage, which is selected, is held in the transistor.

In the present exemplary embodiment, the following advantageous effects are obtained.

As described in the Related Art, information which can be recorded by the normal antifuse corresponds to two values, information “0” or information “1”. When two bits of data of (0, 0), (0, 1), (1, 0), (1, 1) are stored by using such an antifuse, two antifuses becomes necessary.

On the other hand, in the antifuse of the present exemplary embodiment, when information “0”, “1”, “2”, or “3” is assigned in the ascent order or descent order of the threshold voltage, four values of the information can be recorded in one antifuse. In addition, when none of wirings L1 to L4 of break selection wiring 4 is selected, such a condition in which the fuse element does not operate can be recorded as one piece of information. Thus, totally five values of information can be recorded.

The invention of Patent Document 1 needs two antifuses, but only one antifuse is sufficient for the present exemplary embodiment to record any one of four values. Thus, since the antifuse of the present exemplary embodiment is applied to a redundant circuit of a semiconductor memory, the area of the redundant circuit can be reduced by half. As a result, when the number of pieces of information to be stored is three or more, it is possible to reduce a chip size, to increase the number of manufacturable chips per one substrate, and to reduce production cost.

According to the present exemplary embodiment, since more than two values of information can be written in a single antifuse element, when the values of information to be recorded are more than two, a circuit of the semiconductor device can be downsized.

### Second Exemplary Embodiment

While one wiring is selected from the break selection wiring in the first exemplary embodiment, a plurality of wirings are selected as the break selection wiring in the present exemplary embodiment.

A configuration of the antifuse of the present exemplary embodiment will be described.

Unlike the first exemplary embodiment, it is desirable that the wiring resistance of drain electrode 2 of the present exemplary embodiment is as small as possible. Thus, the dopant density in the Poly-Si of drain electrode 2 is adjusted so that the wiring resistance becomes smaller as in the gate electrode of the MOS transistor. It is desirable that the shape of the pattern is a straight line so that the resistance value does not become larger according to the length. Meanwhile, since other configurations are the same as those of the first exemplary embodiment, a detailed description will be omitted.

Next, a method for writing information into the antifuse of the present exemplary embodiment will be described.

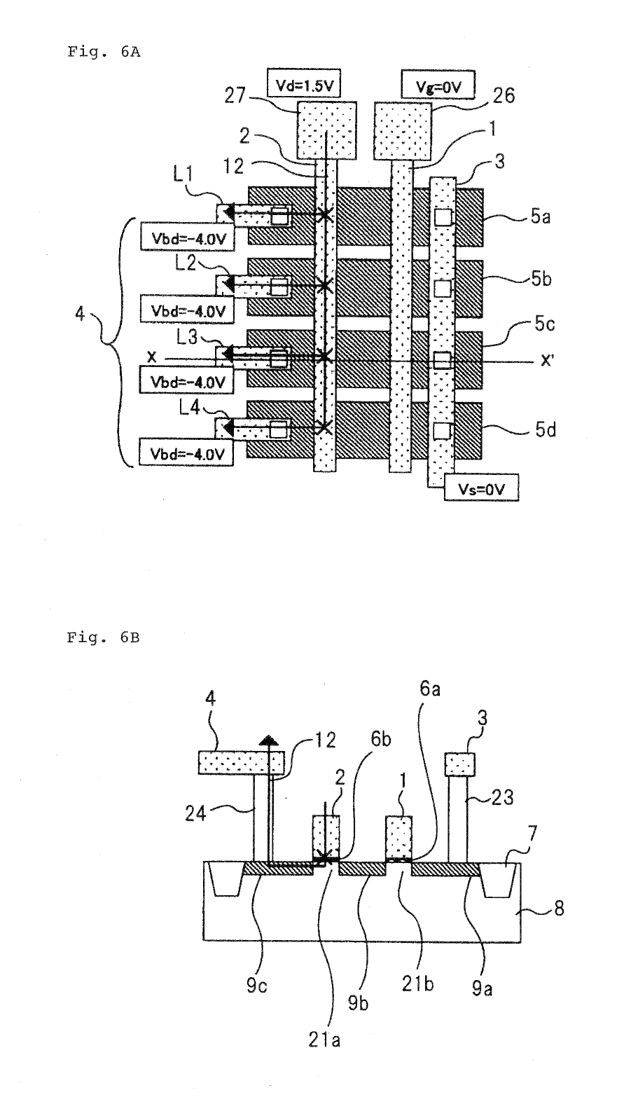

FIG. 6A and FIG. 6B are views describing the method for writing information into the antifuse of the present exemplary embodiment.

A plurality of the wirings are selected from wirings L1 to L4 of break selection wiring 4. Here, all four wirings are selected. The voltage of gate electrode 1, source electrode 3, and semiconductor substrate 8 is caused to be 0 V (earth condition) (Vg=Vs=Vsub=0 V). Vbd=around −4.0 V is applied to each of wirings L1 to L4 as the break down voltage of gate insulation film 6b. The voltage pulse of Vd=around 1.5 V is applied to drain electrode 2. Thereby, in each divided area, gate insulation film 6b of the lower part of drain electrode 2 is broken down, and as illustrated in the current path of arrow 12 of FIG. 6A and FIG. 6B, diffusion layers 9b and 9c of each divided area become conductive with drain electrode 2.

Thereby, the effective gate width W of the MOS transistor is set to the total of each gate width of channel areas 21a of divided areas 5a to 5d.

Next, a method for reading information that has been into the antifuse of the present exemplary embodiment will be described.

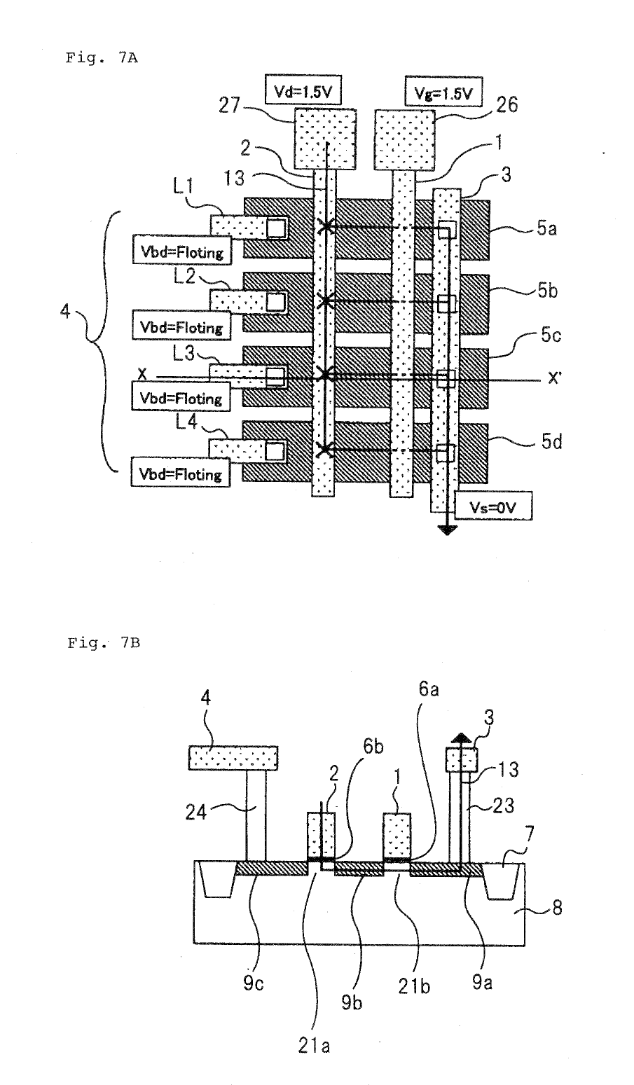

FIG. 7A and FIG. 7B are views describing the method for reading information that has been into the antifuse of the present exemplary embodiment.

All wirings L1 to L4 of break selection wiring 4 are floating states. The voltage for turning on the normal MOS transistor is applied to each of drain electrode 2, gate electrode 1, source electrode 3, and semiconductor substrate 8.

Since gate insulation film 6b of the lower part of drain electrode 2 in divided area 5c is broken down, diffusion layer 9b of the MOS transistor is conductive with drain electrode 2. Thus, when the voltage applied to source electrode 3 and semiconductor substrate 8 is Vs=Vsub=0 V, and when the voltage of Vg=Vd=1.5 V is applied to drain electrode 2 and gate electrode 1, the drain current flows in a current path of arrow 13 as illustrated in FIG. 7A and FIG. 7B. Since the value of the gate width W of the MOS transistor is determined according to the number of the selected wirings for break selection wiring 4, the drain current that corresponds to the gate width W flows.

In the antifuse of the present exemplary embodiment, since one or more wirings are selected from wirings L1 to L4 in break selection wiring 4, and since the voltage for breaking the insulation film of the lower part of drain electrode 2 is applied to the selected wiring, the size of the effective gate width of the transistor is established. When the transistor is turned on, the drain current that corresponds to the determined gate width flows. Since the size of the effective gate width is selected from a plurality of types of the gate width, multiple values of output corresponding to the value of the drain current can be outputted. Even when the transistor is turned off, the gate width, which is selected, is held in the transistor.

In addition, when none of wirings L1 to L4 of break selection wiring 4 is selected, such a condition in which the fuse element does not operate can be recorded as one piece of information. Thus, totally five values of information can be recorded.

Since the antifuse of the present exemplary embodiment is used for the redundant circuit, as in the first exemplary embodiment, it is possible to reduce the chip size, and to reduce the production cost.

Meanwhile, while such a case is described in the above first and second exemplary embodiments in which the conductivity of diffusion layers 9a to 9c is an N type, the conductivity may be a P type. Even when the conductivity of diffusion layers 9a to 9c is the P type, the antifuse of the present invention can be formed, and since a polarity of the voltage applied to each electrode is inverted, the antifuse can be caused to operate as in the above exemplary embodiments. When the P type of diffusion layers 9a to 9c is used, an N-type well may be formed in semiconductor substrate 8, and the P type of diffusion layers 9a to 9c may be arranged in the N-type well.

In the above exemplary embodiments, while a maximum of five values of information can be recorded by providing four MOS transistors, it is sufficient to include at least the two or more MOS transistors. If the two or more MOS transistors are included, a maximum of three values of information can be recorded, and the number of pieces of recordable information is greater than that of the normal antifuse. While such a case has been described in which the number of the break selection wiring is four, the number of the wirings is not limited to four, and may be provided such that the number corresponds to the number of MOS transistors.

Further, the antifuse of the present invention is not limited to only the semiconductor memory, and the present invention can be applied to the fuse of a semiconductor device in which a circuit operation is switched according to the condition of the fuse.

It is apparent that the present invention is not limited to the above embodiments, but may be modified and changed without departing from the scope and spirit of the invention.

What is claimed is:

1. An antifuse element, comprising:
a plurality of MOS transistors;
a first electrode to which source electrodes of said plurality of MOS transistors are commonly connected;
a second electrode to which gate electrodes of said plurality of MOS transistors are commonly connected;
a third electrode to which at least one of drain electrodes of said plurality of MOS transistors is capable of being connected; and
an insulation film provided between said drain electrodes of said plurality of MOS transistors and said third electrode,
wherein insulation on at least one position in said insulation film and that corresponds to one of said drain electrodes is broken down, and thereby said drain electrode corresponding to said position in which said insulation was broken down and said third electrode become conductive with each other.

2. The antifuse element according to claim 1,
wherein any one of said drain electrodes and said third electrode become conductive with each other, and thereby a threshold voltage of said MOS transistor is set corresponding to a resistance value of said third electrode.

3. The antifuse element according to claim 2,
wherein, a length of said third electrode, between a pad, at which voltage is applied, and said insulation film, is different for each of said plurality of MOS transistors.

4. The antifuse element according to claim 2,
wherein electric resistivity of said third electrode is larger than that of said first electrode and said second electrode.

5. The antifuse element according to claim 1,
wherein one or more of said drain electrodes and said third electrode become conductive with each other, and thereby total gate width is set by total of said gate widths of said MOS transistors of one or more of said drain electrodes connected to said third electrode.

6. An antifuse element, comprising:
a plurality of active areas;
a first electrode which is commonly connected to the active areas;
a second electrode which is disposed facing to the active areas with an intervention of a insulation film therebetween; and
a third electrode which is disposed facing to the active areas with an intervention of said insulation film therebetween, wherein
the third electrode is capable of being connected to at least one of the active areas by breakdown of said insulation film.

7. The antifuse element according to claim 6, wherein
a number of data which is recorded by the antifuse element is equal to the number of the active areas or the number being added 1 to the number of the active areas.

8. The antifuse element according to claim 6, wherein
a data which is recorded by the antifuse element is measured by a voltage applying to the second electrode, wherein the voltage is necessary for a current flowing through the first electrode to reach a predetermined value.

9. The antifuse element according to claim 6, wherein
an electric resistance of the third electrode is larger than that of the first electrode and the second electrode.

10. The antifuse element according to claim 6, wherein
the active area comprises a diffusion layer which is N-type or P-type impurity is doped.

11. A method for setting an antifuse element which includes a plurality of MOS transistors; a first electrode to which source electrodes of said plurality of MOS transistors are commonly connected; a second electrode to which gate electrodes of said plurality of MOS transistors are commonly connected; a third electrode to which at least one of drain electrodes of said plurality of MOS transistors is capable of being connected; and an insulation film provided between said drain electrode of said plurality of MOS transistors and said third electrode, said method comprising:
selecting at least one from among said drain electrodes of said plurality of MOS transistors, and
supplying voltage between said selected drain electrode and said third electrode to break down said insulation film to make these electrodes conductive with each other.

12. The method for setting the antifuse element according to claim 11,
wherein any one of said drain electrodes and said third electrode are caused to be conductive with each other, and thereby a threshold voltage of said MOS transistor is set corresponding to a resistance value of said third electrode.

13. The method for setting the antifuse element according to claim 11,
wherein one or more of said drain electrodes and said third electrode are caused to be conductive with each other, and thereby total gate width is set by total of said gate widths of said MOS transistors of one or more of said drain electrodes connected to said third electrode.
